(19) United States
(12) Patent Application Publication
(10) Pub. No.: US 2007/0273012 A1
(43) Pub. Date: Nov. 29, 2007

(54) Semiconductor device

(75) Inventor: Hiroko Ikuta, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki-shi (JP)

(21) Appl. No.: 11/806,843

(22) Filed: Jun. 4, 2007

Related U.S. Application Data
(63) Continuation of application No. PCT/JP04/18118, filed on Dec. 6, 2004.

(51) Int. Cl. H01L 23/495

(52) U.S. Cl. 257/675

(57) ABSTRACT

A semiconductor device comprising, a layer on which a semiconductor element is arranged, an insulation layer on which a wiring connected to the semiconductor element is arranged, dummy metal plates arranged in the insulation layer, wherein the dummy metal plates have an aspect ratio larger than 1, and are arranged substantially perpendicularly to the wiring.

### BACKGROUND OF THE INVENTION

1. Field of the Invention

The present invention relates to a semiconductor device that facilitates dissipation of heat generated when a semiconductor device such as a large-scale integration (LSI) in which a large number of semiconductor elements are integrated is in operation.

2. Description of the Related Art

Miniaturization and super integration of a large-scale integration (LSI) has been promoted recently, and the number of semiconductor elements in an LSI is increasing. However, if formed in high integration while miniaturizing the semiconductor elements, an additional wiring layer is required to connect these semiconductor elements. As a result, wiring length therein becomes long and wiring resistance increases, thereby increasing heat generated from the wiring. Although power consumption per unit can be kept low by highly integrating and miniaturizing a semiconductor element, the power consumption increases as the number of semiconductor elements increases, thereby increasing the heat generated therein.

Therefore, to solve these problems, for example Japanese Patent Application Laid-open No. H10-199882 discloses a semiconductor device in which wiring films and dummy wiring films are formed on wiring layers, and these dummy films are connected to each other between wiring layers above and below via dummy through holes that are provided in each inter-layer insulation film to insulate each of the wiring layers. Moreover, Japanese Patent Application Laid-open No. H11-238734 discloses a semiconductor integrated circuit in which a heat dissipation wiring that is electrically unconnected is provided from a wiring provided on a predetermined layer to a semiconductor substrate that is positioned at a layer below the predetermined layer.

Moreover, Japanese Patent Application Laid-open No. 2002-110902 discloses a semiconductor device that is provided in face-down on a wiring substrate on which terminals are arranged, and that is provided in face-down on a rear surface of a first semiconductor element in which a lead electrode is arranged on the rear surface, and in which a heat dissipation dummy wiring is further provided on the rear surface of the first semiconductor element. Furthermore, Japanese Patent Application Laid-open No. 2004-140286 discloses a semiconductor device that includes a first substrate, a first heat dissipation plate, a rear surface of which is connected to a front surface of the first substrate, a second substrate, of which a rear surface is connected to a front surface of the first heat dissipation plate, a semiconductor chip, of which a front surface is mounted to a front surface of the second substrate in an opposing manner, and a second heat dissipation plate that is connected to a rear surface of the semiconductor chip.

Particularly in a large-scale integration, power consumption is large, and when an electric current is flown through wirings, temperature of the LSI rises due to the heat generated in the wirings. This can be a cause of malfunction. Particularly, in an LSI using a low-dielectric constant insulation film, rise in temperature is large. Although a dummy metal plate has been provided on a via layer to dissipate the heat, there is a problem in which occupancy of the metal plate increases in an insulation layer in a semiconductor device.

This problem is becoming one of dominant causes of signal delay in such a semiconductor device that has multilayer wirings. The signal delay is in proportion to the product of wiring resistance and wiring capacity, and therefore, it is important to reduce the wiring resistance and the wiring capacity to improve the wiring delay.

However, it is a heat dissipation plate, fins, for the substrate on which a semiconductor device is mounted, and is not the one prepared considering heat dissipation of the semiconductor element itself. Furthermore, just by providing the dummy metal plate, such a problem is not solved that the occupancy of the metal plate in the insulation film becomes large.

### SUMMARY OF THE INVENTION

A semiconductor device comprising, a layer on which a semiconductor element is arranged, an insulation layer on which a wiring connected to the semiconductor element is arranged, dummy metal plates arranged in the insulation layer, wherein the dummy metal plates have an aspect ratio larger than 1, and are arranged substantially perpendicularly to the wiring.

### BRIEF DESCRIPTION OF THE DRAWINGS

FIG. 1 is a schematic plan view showing an arrangement of metal plates of a semiconductor device according to the embodiment of the present invention;

FIG. 2 is a cross-section taken along a line A-A′ shown in FIG. 1, and schematically shows heat transfer therein;

FIG. 3 is a cross-section showing an arrangement of conventional dummy metal plates, and schematically shows heat transfer therein;

FIG. 4 is a schematic configuration diagram showing an arrangement of dummy metal plates when a wiring of the semiconductor device is in an L-shape;

FIG. 5 is a schematic configuration diagram showing a shape of elliptic dummy metal plates of the semiconductor device according to the embodiment of the present invention;

FIG. 6 is a schematic configuration diagram showing an arrangement in which dummy metal plates are connected to each other in the semiconductor device;

FIG. 7 is a schematic diagram showing a configuration of a CMOS semiconductor device used in a simulation;

FIG. 8 is a graph showing a result of a simulation of thermal resistance with respect to an aspect ratio of the dummy metal plates using width of the wiring as a parameter;

FIG. 9 is a graph showing a result of a simulation of thermal resistance with respect to the aspect ratio of the dummy metal plates when a surface occupied by the dummy metal plates is made constant, using the width of the wiring as a parameter; and

FIG. 10 is a graph showing a result of a simulation of the thermal resistance with respect to the aspect ratio of the dummy metal plates when a surface occupied by the dummy metal plates on a via layer is made constant, using the width of the wring as a parameter.

### DETAILED DESCRIPTIONS

The explanations below will only exemplify the embodiments of the present invention, and the exemplary embodiments do not limit the scope of the appended claims. Other embodiments will readily occur to those skilled in the art through changes and modifications of the invention within the scope of the appended claims, and these changes and modifications are also embraced in the scope of the claims.

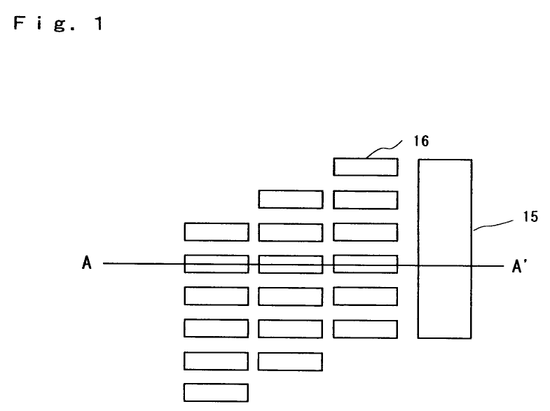

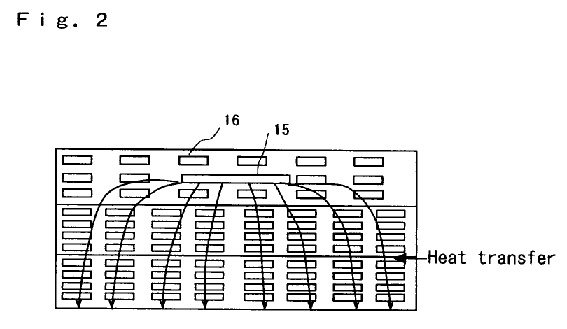

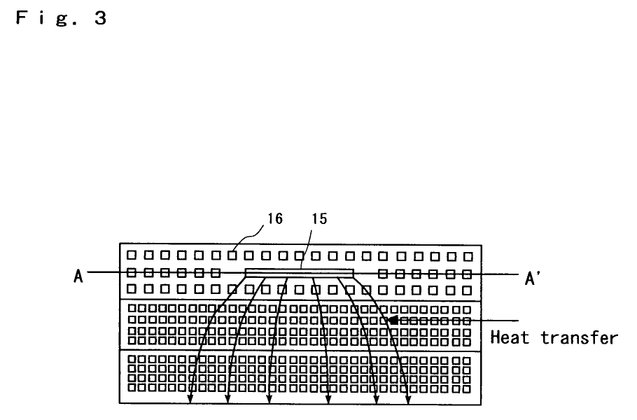

FIG. 1 is a schematic plan view showing an arrangement of metal plates of a semiconductor device according to the embodiment. FIG. 2 is a cross-section taken along a line A-A′ shown in FIG. 1, and is a schematic diagram showing heat transfer therein. FIG. 3 is a cross-section showing an arrangement of conventional dummy metal plates, and is a schematic diagram showing heat transfer therein.

As shown in FIG. 1, in a semiconductor device 1 according to the embodiment, a wiring 15 is provided to supply a current or to communicate signals, and dummy metal plates 16 that are not involved in conduction of electricity that causes the semiconductor to operate. If a current flows due to the operation of the semiconductor device 1, deterioration of a semiconductor element 2 in the semiconductor device 1 is accelerated. Specifically, an operation speed of the semiconductor element 2 such as a transistor in the semiconductor device 1 becomes slow, thereby causing malfunction.

Therefore, the dummy metal plates 16 formed with a material having a high thermal conductivity are provided on a layer on which the wiring 15 is provided, thereby lowering the thermal resistance by causing the heat to be transferred from the wiring 15, and thereby preventing local rise in temperature in the semiconductor device 1 by causing the heat to be transferred to the entire part of the semiconductor device 1. For a material having a high electrical conductivity such as metal, it can be said, in general terms, that the higher the electrical conductivity, the higher the thermal conductivity. Therefore, the heat generated in the wiring 15 is transferred with the dummy metal plates 16 to prevent the local rise in temperature, while dispersing the heat to be discharged so that heat dissipation is facilitated. At this time, the dummy metal plates 16 are configured to have a ratio m of width and length (hereinafter, “aspect ratio”) larger than 1. If the aspect ratio is 1, heat transfer occurs equally in four directions; therefore, an effect of facilitating the heat dissipation is small. By setting the aspect ratio of the dummy metal plates 16 to a value larger than 1, heat transfer in a predetermined direction is facilitated, thereby lowering the thermal resistance and lowering temperature around the wiring.

As shown in FIG. 1 and FIG. 2, the dummy metal plates 16 are arranged such that a longitudinal direction of the dummy metal plates 16 is perpendicular to the wiring 15. Since the wiring 15 is surrounded by a homogeneous insulator, the heat is transferred in each direction at the same speed. However, when the heat reaches the dummy metal plates 16, the dummy metal plates 16 become the same temperature because of the high thermal conductivity. Further, because of the temperature difference, the heat is speedily transferred in a direction of entering from an end from which the heat enters. Accordingly, a speed of heat transfer from one dummy metal plate 16 to another dummy metal plate 16 becomes high, and a speed of lowering the temperature of the wiring 15 also becomes high. Furthermore, as being farther away from the wiring 15, temperature is lower and the temperature difference becomes larger; therefore, the speed of heat transfer becomes higher, thereby lowering the thermal resistance. Thus, a speed of heat transfer from the wiring 15 to a position low in temperature and far from the wiring becomes high, thereby lowering the temperature of the wiring 15.

If the aspect ratio of the dummy metal plates 16 is 1, as shown in FIG. 3, the heat generated in the wiring 15 is uniformly transferred all around with respect to an insulation material therearound to reach the dummy metal plates 16. Although the dummy metal plates 16 soon become the same temperature, the heat is transferred also from an end on a side-surface side in a vertical direction in the example shown in FIG. 3 since the aspect ratio of the dummy metal plates 16 and temperature difference within each of the dummy metal plates 16 are small. In addition, since the temperature difference is small, a transfer speed of the heat is low in any direction of the dummy metal plates 16, and the effect of lowering the temperature of the wiring 15 is small. Accordingly, an effect of lowering the temperature of the semiconductor device 1 is small.

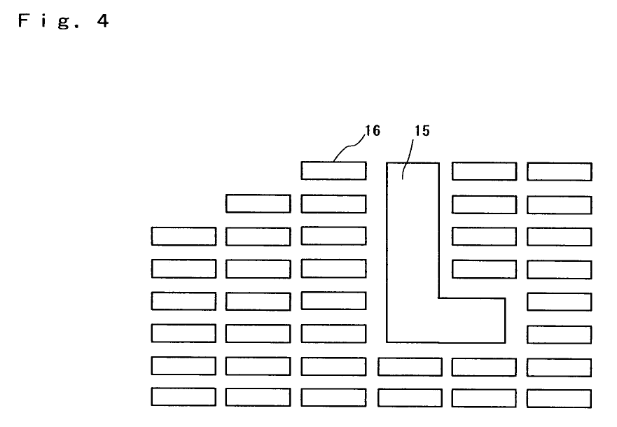

FIG. 4 is a schematic configuration diagram showing an arrangement of dummy metal plates when a wiring of a semiconductor device is in an L-shape. In the semiconductor device 1 according to the embodiment, the dummy metal plates 16 are arranged perpendicularly to a side of the wiring 15 having the longest length. Particularly, as shown in FIG. 4, when the wiring 15 of the semiconductor device 1 is not rectangular, but bent in an L-shape, a T-shape, etc., the dummy metal plates 16 are arranged perpendicularly to a side of the wiring 15 having the longest length. Since the heat generated in the wiring 15 is transferred more from a long side than a short side, it is possible to more effectively facilitate transfer and dissipation of the heat to lower the thermal resistance by arranging the dummy metal plates 16 with respect to the long side, thereby lowering the temperature of the semiconductor device 1.

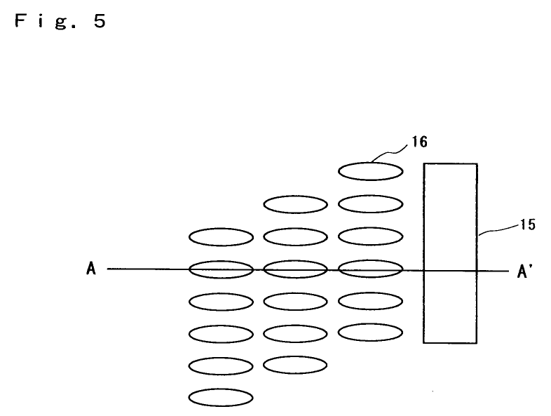

FIG. 5 is a schematic configuration diagram showing elliptic dummy metal plates of the semiconductor device according to the embodiment. A shape of the dummy metal plates 16 used herein is not specifically limited as long as the aspect ratio, which is the ratio of width and length, is larger than 1. For example, the shape thereof can be rectangular, elliptic, or rhomboid. Particularly, in a view point of arranging perpendicularly to the wiring 15, a rectangular shape is most preferable since more heat can be received as a side opposing to the wiring 15 becomes larger. Furthermore, the aspect ratio of the dummy metal plates 16 can be determined depending on an arrangement of other wirings, the semiconductor device 1, and contact holes within the semiconductor device 1, as long as the aspect ratio is larger than 1.

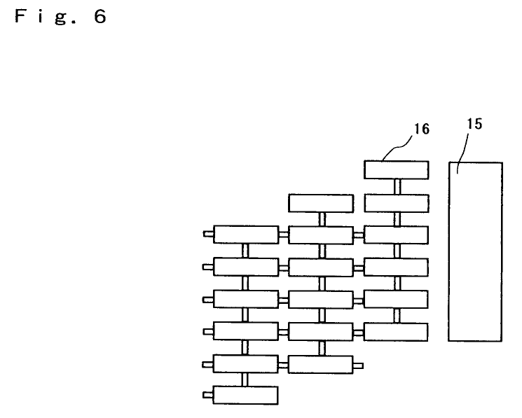

Moreover, FIG. 6 is a schematic configuration diagram showing an arrangement in which dummy metal plates are connected to each other in the semiconductor device. In the semiconductor device 1 according to the embodiment, the dummy metal plates 16 are connected to each other. The dummy metal plates 16 to be connected can be a part of the dummy metal plates 16 or all of the dummy metal plates 16. When the dummy metal plates 16 are surrounded by the insulation material having low thermal conductivity, a speed of heat transfer from one dummy metal plate 16 to another dummy metal plate 16 is low, however, if the dummy metal plates are connected to each other, an obstacle to the heat transfer is eliminated and the speed of the heat transfer increases, thereby lowering the thermal resistance.

Furthermore, the semiconductor device 1 is formed in a multilayer wiring structure having a plurality of layers on which a wiring is arranged, and is communicated to interlayer insulation films 21 provided thereon and thereunder. Particularly, in the semiconductor device 1 in which a wiring 15A from a power source is provided on the uppermost layer, the percentage of heat transfer inside the semiconductor device is higher than that of thermal dissipation to the air. Since thermal conductivity of air is low, the thermal dissipation to the air is small unless a flow of air and convection is large. Therefore, the heat generated in the wiring has a high percentage of transferring in the insulation material that has small thermal conductivity compared to an electrically conductive material such as metal. Therefore, the heat generated in the wiring is transferred in a lateral direction and a downward direction in the semiconductor device 1.

In the semiconductor device 1 according to the embodiment, the dummy metal plates 16 are arranged on an inter-layer insulation film (hereinafter, “wiring layer”) on which the wiring 15 is provided or on an inter-layer insulation film (hereinafter, “via layer”) on which via holes 14 are formed. The layer on which the wiring is arranged has a little space to provide the dummy metal plates 16, and the heat generated in a wiring network is transferred faster in the conductive wiring than to the surroundings on the layer from the semiconductor element 2. Therefore, by providing the dummy metal plates 16 on the wiring layer, it is possible to facilitate transfer and dissipation of the heat generated in the wiring network.

Moreover, the dummy metal plates 16 are arranged on the via layer. Similarly to the wiring layer, the via holes 14 are also connected to the semiconductor element 2, the wiring 15, and the like, and since an electrically conductive material having high thermal conductivity is provided, heat transfer speed is high. Therefore, by providing the dummy metal plates 16 on the via layer, it is possible to facilitate transfer and dissipation of the heat generated in the wiring network.

Furthermore, in the semiconductor device 1 according to the embodiment, the dummy metal plates 16 are provided only under the power source wiring 15A. Since the large current flows through the power source wiring 15A among the wirings in the semiconductor device 1, the heat is generated most from the power source wiring 15A. Such a large current can cause delay of signals and the like. To avoid such an influence to the semiconductor element 2 and the like, the power source wiring 15A is provided at the uppermost portion or at an adjacent portion thereof. By providing the dummy metal plates 16 under the power source wiring 15A, it is possible to facilitate transfer and dissipation of the generated heat to prevent rise in temperature of the wiring layer of the power source wiring 15A.

In the semiconductor device 1 according to the embodiment, the insulation material of the inter-layer insulation film on which the dummy metal plates 16 are arranged is composed of an insulation material having relative permittivity equal to or lower than 4.

As miniaturization and high integration of the semiconductor device 1 such as an LSI advance, the operation speed decreases due to RC delay of the wiring layer and power consumption increases due to increase of inter-layer capacitance. Therefore, by using a metal material having low wiring resistance and an insulation material having low relative permittivity for the inter-layer insulation film, reduction of the operation speed of the semiconductor element 2 can be prevented. Relative permittivity of the insulation material is preferable to be equal to or lower than 4, particularly, equal to or lower than 3.6, and further preferable to be equal to or lower than 2.7.

A material having lower relative permittivity can be selected from an oxide such as SiO₂, F-doped SiO₂, C-doped SiO₂ (SiOC), B-doped SiO₂, and porous SiO₂ (NCS), or a polymer such as polysilsesquioxane containing hydrogen, polyimid, Polyarylether (SiLK®), and resin fluoride (Teflon®).

Moreover, in the semiconductor device 1 according to the embodiment, the same metal as a material of the wiring 15 is used for the dummy metal plates 16. If a different metal from the wiring 15 is used when the dummy metal plates 16 are arranged on the wiring layer or the via layer, manufacturing process becomes complicated, thereby causing a manufacturing cost problem. In the semiconductor device 1 according to the embodiment, a metal for the wiring can be selected from Al, an Al alloy such as Al—Si and Al—Cu—Si, Cu, and a Cu alloy such as Cu—P and Cu—Zn. Electromigration is less likely to occur in Cu and a Cu alloy, and Cu has high electrical conductivity and high thermal conductivity; therefore, a heat value from the wiring becomes small, and it is excellent in dissipation of the heat. Al and an Al alloy have excellent adhesion with SiO₂ of the insulation material. These alloys and the like can be selectively used depending on a position of use in the semiconductor device 1. The dummy metal plates 16 and the wiring 15 are formed by a vacuum deposition method and the like of a spattering method, and by performing a planarization process, the semiconductor device 1 having the multilayer wiring structure is formed.

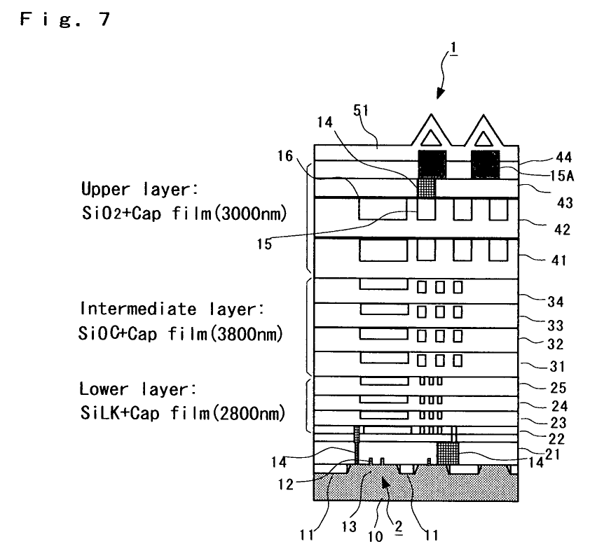

FIG. 7 is a schematic diagram showing a configuration of a CMOS semiconductor device used in a simulation. The CMOS semiconductor device 1 is formed in nine layers, and in the lower four layers, SiLK is used as an insulation material, and thickness is 2800 nm including a Cap film, in the intermediate three layers, SiOC is used as an insulation material, and thickness is 3800 nm including a Cap film, and in the upper two layer, SiLK is used as an insulation material, and thickness is 3000 nm including a Cap film.

For the wiring 15 and the dummy metal plates 16, Cu is used. The shape of the dummy metal plates 16 is rectangular, and the dummy metal plates 16 are arranged perpendicularly to the wiring 15. For a temperature analysis, a finite element method is used. In this finite element method, thermal resistance of each material in series connection can be calculated by substituting thermal conductivity of each material. A current of 3×10⁵A/cm² is applied to the power source wiring 15A.

(Simulation 1)

Thermal resistance (K/W) from the layer of the power source wiring 15A to the layer at which the semiconductor element 2 is arranged was analyzed when the dummy metal plates 16 are arranged at regular intervals while changing the aspect ratio of the dummy metal plates 16 and using the width of the wiring 15 as a parameter. This thermal resistance is defined by Equation (1) below.
temperature rise(deg)=generated heat(W)×thermal resistance (K/W) Equation (1)

If this thermal resistance is high, rise in temperature becomes large even with the same heat value. Therefore, if the thermal resistance is low, the heat generated in the wiring is quickly transferred and the temperature of the semiconductor device 1 becomes uniform.

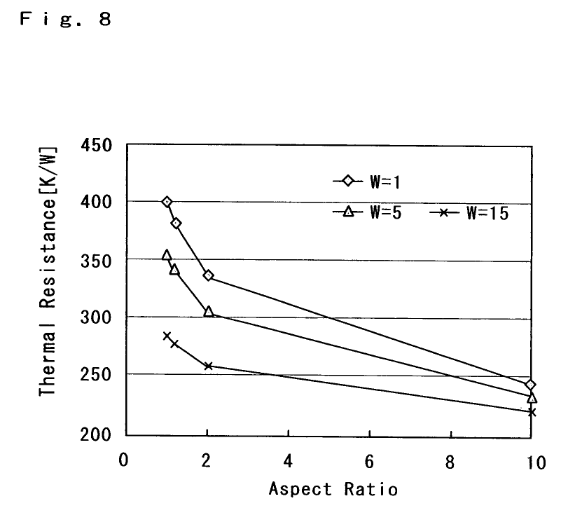

FIG. 8 is a graph showing a result of simulation of thermal resistance from the lowermost layer to the upper most layer with respect to an aspect ratio of the dummy metal plates using a width of the wiring as a parameter. Results when the width of the wiring is 1 μm, 5 μm, and 15 μm are shown.

The result of the simulation is shown in Table 1.

TABLE 1
Relation Among the Aspect Ratio of the Dummy
Metal Plate, Thermal Resistance, and Temperature
Rise When the Wiring Width is 15 μm

| | Thermal resistance | Temperature rise |
|---|---|---|
| Aspect ratio | (K/W) | (deg) |
| 1 | 284 | 471 |
| 2 | 258 | 406 |
| 10 | 222 | 331 |

As is evident from FIG. 8, as the wiring width becomes thin, the thermal resistance becomes high and the heat value becomes large. Moreover, from Table 1, when the aspect ratio of the dummy metal plates 16 becomes large, the thermal resistance remarkably decreases and the temperature rise becomes small. The temperature rise is shown based on the temperature at the power source wiring 15A of the semiconductor device 1 when the aspect ratio 1. By setting the aspect ratio large, it is possible to suppress the temperature rise in the semiconductor device 1 with a profound effect.

(Simulation 2)

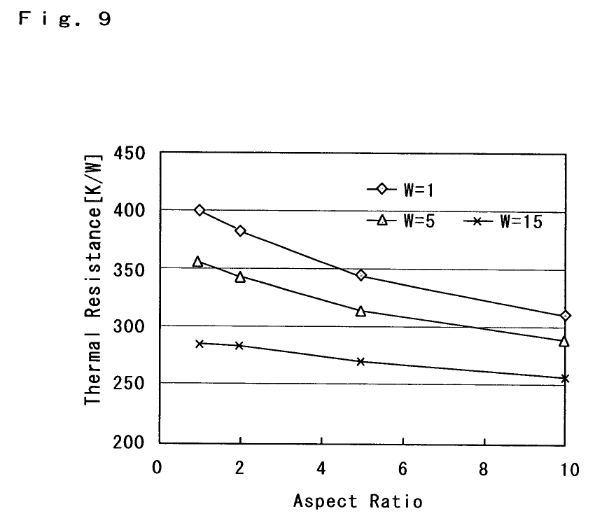

FIG. 9 is a graph showing a result of simulation of thermal resistance with respect to the aspect ratio of the dummy metal plates when a surface occupied by the dummy metal plates is made constant, using the width of the wiring as a parameter.

The result of the simulation is shown in Table 2.

TABLE 2
Relation Among the Aspect Ratio of the Dummy
Metal Plate, Thermal Resistance, and Temperature
Rise When the Wiring Width is 15 μm

| | Thermal resistance | Temperature rise |
|---|---|---|
| Aspect ratio | (K/W) | (deg) |
| 1 | 284 | 473 |
| 5 | 269 | 433 |
| 10 | 258 | 405 |

As is evident from FIG. 9 and Table 2, the thermal resistance remarkably decreases when the aspect ratio of the dummy metal plates 16 becomes large. Moreover, it is found that similarly, by setting the aspect ratio large, it is possible to suppress the temperature rise in the semiconductor device 1 remarkably.

(Simulation 3)

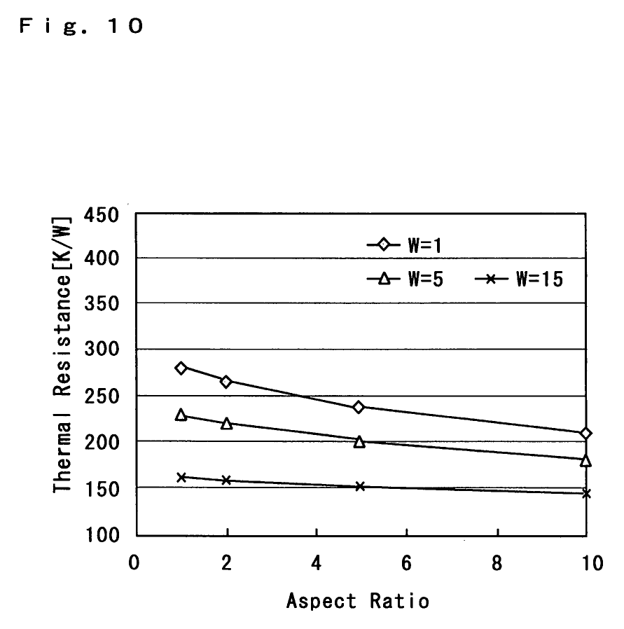

FIG. 10 is a graph showing a result of simulation of the thermal resistance with respect to the aspect ratio of the dummy metal plates when a surface occupied by the dummy metal plates on a via layer is made constant, using the width of the wring as a parameter.

TABLE 3
Relation Among the Aspect Ratio of the Dummy
Metal Plate, Thermal Resistance, and Temperature
Rise When the Wiring Width is 15 μm

| | Thermal resistance | Temperature rise |
|---|---|---|
| Aspect ratio | (K/W) | (deg) |
| 1 | 161 | 235 |
| 5 | 153 | 225 |
| 10 | 149 | 219 |

As is evident from FIG. 10 and Table 3, the thermal resistance remarkably decreases when the aspect ratio of the dummy metal plates 16 becomes large. Moreover, it is found that similarly, by setting the aspect ratio large, it is possible to suppress the temperature rise in the semiconductor device 1 remarkably.

### EXAMPLES

A configuration of the semiconductor device 1 according to the embodiment in which the dummy metal plates 16 are arranged is explained below. As shown in FIG. 7, on a semiconductor substrate 10, a plurality of regions for the semiconductor element 2 are provided. Around the regions of the semiconductor element 2, element separation films 11 are provided. On the semiconductor substrate 10, the element separation films 11 to define the element regions are formed by, for example, an STI method. As shown in FIG. 7, on the semiconductor substrate 10 on which the element separation films 11 are formed, a MOS transistor having a gate electrode 12 and a source/drain diffusion layer 13 is formed similarly to the manufacturing of ordinary MOS transistors. On the semiconductor substrate 10 on which the MOS transistor is formed, a via layer 21 as an inter-layer insulation film composed of a silicon oxide film in which a contact plug is embedded is formed. Planarization is performed on the surface of the insulation film by polishing the surface of the insulation film by, for example, a CMP method. Subsequently, the via layer 21 is opened by photolithography and dry etching, and the via layer 21 having the via holes 14 reaching the semiconductor substrate 10 in the inter-layer insulation film is formed by a CVD method when W is used as a metal, and by a plating method when Cu is used as a metal.

On this via layer 21, an inter-layer insulation film 22 that has a layered structure of SiC film/SiLK film/SiC film is formed. For example, a Ti (titanium) film having film thickness of 15 nm, a TiN (titanium nitride) film having film thickness of 10 nm, and a W (tungsten) film having film thickness of 250 nm are formed by the CVD method. Subsequently, the W film, the TiN film, and the Ti film are removed evenly until the surface of the insulation film is exposed by the CMP method, to be embedded in the via holes. Thus, the contact plug formed with the Ti film, the Tin film, and the W film is formed. Subsequently, on the inter-layer insulation film 21 in which the contact plug is embedded, an SiC film having film thickness of, for example, 30 nm is deposited by the CVD method. On the SiC film, an SiLK film having film thickness of, for example, 450 nm is formed, for example, by a spin coat method. On the SiLK film, an SiC film having film thickness of, for example, 30 nm is formed by, for example, the CVD method. Thus, the inter-layer insulation film 22 having the layered structure of SiC film/SiLK film/SiC film is formed. The SiC film on the Cap layer functions as an etching stopper film and as diffusion preventing film of Cu.

In this inter-layer insulation film 22, the wiring 15 and the dummy metal plates 16 are embedded in an internal circuit region and around the region, respectively. The wiring 15 and the dummy metal plates 16 are formed on the same layer. On this inter-layer insulation film 22, three inter-layer insulation films 23, 24, and 25 having the same layered structure as the inter-layer insulation film 22 are formed. In the inter-layer insulation films 23, 24, and 25, the wiring 15, the dummy metal plates 16, and the via holes 14 are embedded.

Furthermore, on these three inter-layer insulation films 23, 24, and 25, an inter-layer insulation film 31 having a layered structure of SiOC film/SiC film/SiOC film/SiC film is formed. To form this inter-layer insulation film 31, an SiC film having film thickness of 50 nm, an SiO film having film thickness of 500 nm, an SiC film having film thickness of 50 nm, an SiOC film having film thickness of 400 nm, and an SiC film having film thickness of 50 nm are sequentially deposited, and an insulation film having the layered structure of SiC film/SiOC film/SiC film/SiOC film/SiC film is formed.

A photoresist film exposing a region in which the vial holes 14 are to be formed is formed by photolithography. At this time, a pattern to form the dummy metal plates are formed around the via holes 14. Subsequently, the photoresist is removed. After a nonphotosensitive resin is applied by the spin coat method, the nonphotosensitive resin on the inter-layer insulation film 31 is dissolved and removed such that the nonphotosensitive resin remains inside the via holes. Subsequently, on the inter-layer insulation film 31 in which the nonphotosensitive resin is embedded, a photoresist film is formed that exposes a regions in which the wiring layer 15 and the dummy metal plates 16 are to be formed, by photolithography. The SiC film and the SiOC film are anisotropic etched using the photoresist film as a mask and the SiC film as a stopper, to form a wiring groove to embed the wiring 15 and grooves to embed the dummy metal plates 16. After the nonphotosensitive resin is removed together with the photoresist film, the SiC film is anisotropic etched to remove the SiC film, and the via holes, the wiring 15, and the dummy metal plates 16 are formed. This process is repeated, to form the wiring 15 and the dummy metal plates 16 that are embedded in inter-layer insulation films 32, 33, and 34. Thus, on this inter-layer insulation film 31, the three inter-layer insulation films 32, 33, and 34 in which the wiring 15, the dummy metal plates 16 similarly to the inter-layer insulation film on the lower layer, and the via holes 14 are embedded and that has the layered structure are formed as the intermediate layer.

Furthermore, on this intermediate layer 32, 33, and 34, inter-layer insulation films 41, 42, 43, and 44 having a layered structure of SiO₂ film/SiC film/SiO₂ film/SiC film are formed as the upper layer. The above process is repeated using an SiO film instead of the SiOC film, and the wiring 15, the dummy metal plates 16, and the via holes 14 are formed that are embedded in the insulation film. Subsequently, on the inter-layer insulation film 41, an SiC film having film thickness of 50 nm and an SiO film having film thickness of 500 nm are formed, for example, by the CVD method, to form the inter-layer insulation film 42 having the layered structure of SiO film/SiC film. On this insulation film 43, the via hole 14 is embedded to form a via layer. On this insulation film 43, the power source wiring 15A connected to a contact plug is formed. On the inter-layer insulation film 43 in which the contact plug is embedded, a TiN film having film thickness of 100 nm, a Cu film having film thickness of 900 nm, and a TiN film having film thickness of 50 nm are deposited, for example, by the spattering method. Patterning is then process on the layered film of TiN film/Cu film/TiN film by photolithography and dry etching, to form the wiring 15.

On this insulation film 44, an SiO film having film thickness of 1200 nm and an SiN film having film thickness of 400 nm are deposited, for example, by the CVD method, to form a cover film 51 having a layered structure of SiN film/SiO film.

The dummy metal plates 16 are formed using Cu that is the same material as that of the wiring by a dual damascene process.

In the semiconductor device 1 according to the embodiment, the dummy metal plates 16 adjacent in a direction of film thickness are connected, and therefore, mechanical strength, particularly, in the direction of film thickness, of the inter-layer insulation films therearound increases. Furthermore, thermal resistance in the direction of film thickness from the wiring 15 and a via 17 is lowered, thereby facilitating heat transfer.

According to the embodiment, by the above means for solving the problems, the dummy metal plates having a large aspect ratio are provided on the same layer as the wiring in the semiconductor device according to the embodiment, thereby lowering thermal resistance without increasing relative permittivity of the insulation layer, to facilitate heat transfer of the heat generated from the wiring. Thus, it is possible to suppress temperature rise of the semiconductor device during the operation.

What is claimed is:

1. A semiconductor device comprising:
a layer on which a semiconductor element is arranged;
an insulation layer on which a wiring connected to the semiconductor element is arranged;
dummy metal plates arranged in the insulation layer;
wherein the dummy metal plates have an aspect ratio larger than 1, and are arranged substantially perpendicularly to the wiring.

2. The semiconductor device according to claim 1, wherein
the dummy metal plates are arranged perpendicularly to a side of the wiring having longest length.

3. The semiconductor device according to claim 2, wherein
the dummy metal plates are arranged perpendicularly to a side of an L-shaped wiring, the side having longest length.

4. The semiconductor device according to claim 1, wherein
the dummy metal plates are arranged on any one of a wiring layer and a via layer.

5. The semiconductor device according to claim 1, wherein
the dummy metal plates have any one of a rectangular shape and a elliptic shape.

6. The semiconductor device according to claim 1, wherein
a part of or all of the dummy metal plates are connected to each other.

7. The semiconductor device according to claim 1, wherein
the insulation layer has relative permittivity equal to or lower than 4.

8. The semiconductor device according to claim 7, wherein
the insulation layer is formed mainly with SiO₂, SiOC, SiLK, and NCS.

9. The semiconductor device according to claim 1, wherein
the dummy metal plates are formed with an identical material to a material of the wiring.

10. The semiconductor device according to claim 9, wherein
the dummy metal plates are formed with a material selected from among Al, Cu, an Al alloy, and a Cu alloy.
